(19) United States
(12) Patent Application Publication
(10) Pub. No.: US 2008/0157271 A1
(43) Pub. Date: Jul. 3, 2008

(54) SEMICONDUCTOR DEVICE HAVING ANTIFUSE AND METHOD OF MANUFACTURING THE SAME

(75) Inventor: Kazumasa SUZUKI, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/962,233

(22) Filed: Dec. 21, 2007

(30) Foreign Application Priority Data
Dec. 22, 2006 (JP) 2006-346474

(51) Int. Cl. H01L 23/525; H01L 21/768

(52) U.S. Cl. 257/530; 438/600; 257/E23.148; 257/E21.592

(57) ABSTRACT

A semiconductor device has a semiconductor substrate, an insulating layer formed on the semiconductor substrate, a wiring formed in the insulating layer and an antifuse including first and second connecting portions coupled to the wiring. The anti fuse has a space provided between the first connecting portion and the second connecting portion and insulating the first connecting portion from the second connecting portion. The first connecting portion and the second connecting portion may be coupled by a conductive material disposed in the space.

### CROSS-REFERENCE TO RELATED APPLICATIONS

This application is based upon and claims the benefit of priority from the prior Japanese Patent Application No. 2006-346474, filed Dec. 22, 2006, the entire contents of which are incorporated herein by reference.

### BACKGROUND OF THE INVENTION

1. Field of the Invention

This invention relates to semiconductor devises and methods of manufacturing semiconductor devices, particularly semiconductor devices having an antifuse and methods of manufacturing the same.

2. Description of the Related Art

A conventional semiconductor device having antifuses is known. An antifuse changes a connection state from an insulated state by applying voltage thereto.

A conventional semiconductor device has a semiconductor substrate, an insulated layer formed on the semiconductor substrate, a lower wiring layer formed on the insulated layer, an amorphous semiconductor layer for antifuse formed on the lower wiring layer, an inter-layer dielectric formed on the insulated layer and the and the amorphous semiconductor layer and having a contact hole which reaches to the amorphous semiconductor layer, and an upper wiring layer formed on the inter-layer dielectric connected to the amorphous semiconductor layer through the contact hole.

According to the semiconductor device, Joule heat is generated by applying voltage between the upper wiring layer and the lower wiring layer. A part of the amorphous semiconductor layer can thereby be changed into a polycrystal, the resistance thereby lowered, and the upper wiring layer and the lower wiring layer thereby electrically connected.

However, when an element domain is near the antifuse domain, there is a possibility that the element domain (for example, gate insulating film etc.) may be damaged by applying voltage between the upper wiring layer and the lower layer wiring layer.

### BRIEF SUMMARY OF THE INVENTION

Accordingly to one aspect of the present invention, there is provided a semiconductor device including a semiconductor substrate, a insulating layer formed on the semiconductor substrate, a wiring formed in the insulating layer, and an antifuse including first and second connecting portions coupled to the wiring the antifuse having an space between the first connecting portion and the second connecting portion, the space having a width insulating the first connecting portion from the second connecting portion, the first connecting portion and the second connecting portion configured to be coupled by a conductive material disposed in the space.

A semiconductor device according to an another aspect of the present invention includes a semiconductor substrate, a insulating layer formed on the semiconductor substrate, a wiring formed in the insulating layer, a first antifuse including first and second connecting portions coupled to the wiring, the first connecting portion and the second connecting portion coupled by a conductive material, and a second antifuse including third and fourth connecting portions coupled to the wiring, the second antifuse having a space between the third connecting portion and the fourth connecting portion, the space having a width insulating the third connecting portion from the fourth connecting portion.

A method of fabricating a semiconductor device according to an another aspect of the present invention includes preparing a semiconductor substrate, a insulating layer formed on the semiconductor substrate, a wiring formed in the insulating layer and a antifuse including a first connecting portion and a second connecting portion, the antifuse having a space, between the first connecting portion and the second connecting portion, and disposing a conductive material in the space so as to couple the first connecting portion to the second connecting portion.

A semiconductor device according to an another aspect of the present invention includes a semiconductor substrate, an insulating layer formed on the semiconductor substrate, a wiring formed in the insulating layer, a first antifuse including first and second connecting portions coupled to the wiring, the first connecting portion and the second connecting portion coupled by a conductive material, and a second antifuse including third and fourth connecting portions coupled to the wiring, the second antifuse having an space between the third connecting portion and the fourth connecting portion, the space having a width insulating the third connecting portion from the fourth connecting portion, wherein the conductive material is a ball bump, the first antifuse is coupled to a normal circuit, and the second antifuse is coupled to a defective circuit.

### BRIEF DESCRIPTION OF THE SEVERAL VIEWS OF THE DRAWING

A more complete appreciation of the invention and many of the attendant advantages thereof will be readily obtained as the same becomes better understood by reference to the following detailed description when considered in connection with the accompanying drawings, wherein:

FIG. 1 is a top view of an antifuse region in a semiconductor device according to a first embodiment of the invention.

FIG. 2 is a sectional view of the semiconductor device taken along line A-A of FIG. 1 according to a first embodiment of the invention.

FIG. 3A is a sectional view illustrating a method of making the semiconductor device according to a first embodiment of the invention.

FIG. 3B is a sectional view illustrating a method of making the semiconductor device according to a first embodiment of the invention.

FIG. 3C is a sectional view illustrating a method of making the semiconductor device according to a first embodiment of the invention.

FIG. 4 is a top view of an antifuse region in a semiconductor device according to a second embodiment of the invention.

FIG. 5 is a sectional view of the semiconductor device taken along line B-B of FIG. 4 according to a second embodiment of the invention.

FIG. 6A is a sectional view illustrating a method of making the semiconductor device according to a second embodiment of the invention.

FIG. 6B is a sectional view illustrating a method of making the semiconductor device according to a second embodiment of the invention.

FIG. 6C is a sectional view illustrating a method of making the semiconductor device according to a second embodiment of the invention.

### DETAILED DESCRIPTION OF THE INVENTION

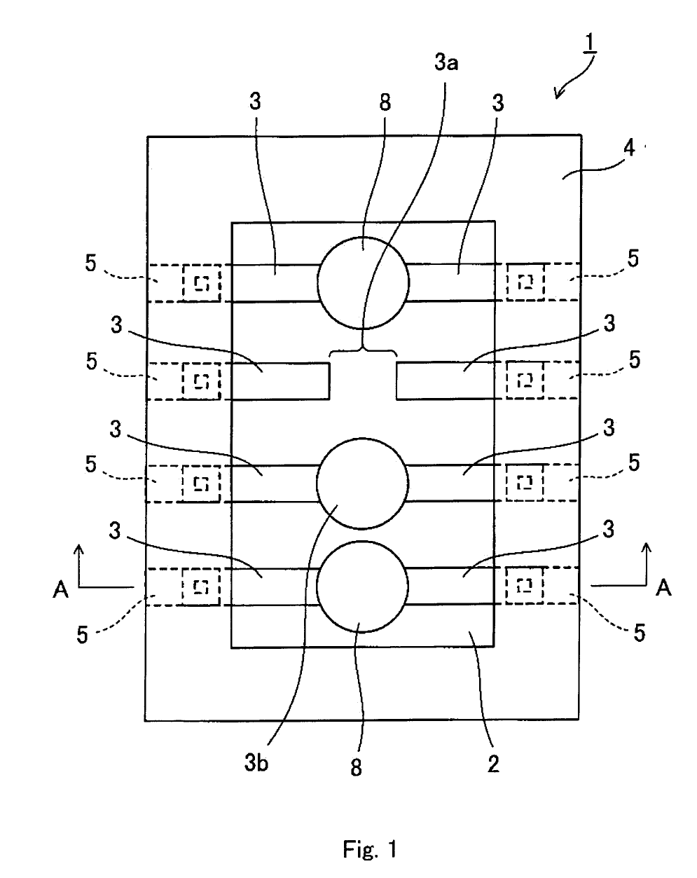

Various other objects, features and attendant advantages of the present invention will be more fully appreciated as the same becomes better understood from the following detailed description when considered in connection with the accompanying drawings in which like reference characters designate like or corresponding parts throughout the several views and more particularly to FIG. 1 thereof.

### First Embodiment

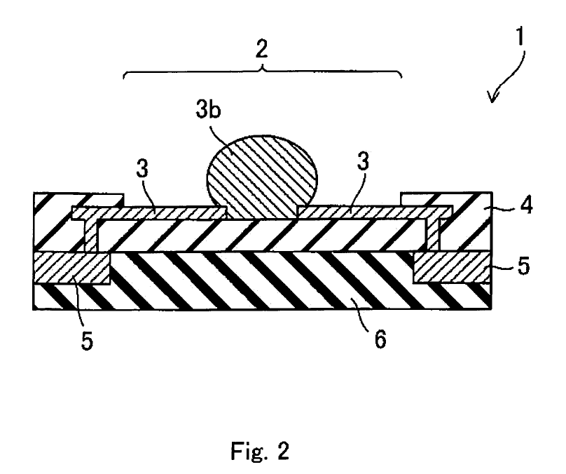

Referring now to FIG. 1, semiconductor device 1 has two or more antifuses 3. As shown in FIGS. 1 and 2, each antifuse 3 is formed in protection insulating film 4, and has an exposed the surface in antifuse domain 2. Each antifuse 3 is connected to wiring 5 formed in interlayer insulating film 6, respectively.

Antifuse 3 is made of two wiring elements (wiring elements on either side in FIG. 1) electrically opened by space 3a in antifuse domain 2. Among these, spaces 3a of specific antifuses 3 (first, third and fourth antifuses 3 from the top in FIG. 1) are buried by ball bump 3b, and the two wirings of these antifuses 3 are electrically connected. For example, first third, and fourth antifuses 3 from the top in FIG. 1 are connected to a circuit which operates normally, and the second antifuse 3, which is not connected by a ball bump 3b, is connected to a defective circuit.

Antifuse 3 is made of conductive material, such as aluminum. Wiring 5 is made of conductive material, such as Cu.

As a ball bump 3b, conductive materials such as solder, Au, Cu and an alloy containing these or the like can be used. In addition, the melting point of ball bump 3b may be more than 240 degrees (° C.). The melting point is chosen sufficiently high because there is a possibility of melting by a heating process (for example, a heating process for activating impurity ions implanted into a transistor domain) if the melting point is too low. The ball bump 3b may have other features than as specifically shown, for example a shape of a board, may be used.

As a protection insulating film 4, insulating materials such as TEOS (Tetraethoxysilane), SiN, and polyimide or the like can be used Especially, hygroscopic low material, such as TEOS and SiN, is desirable.

As interlayer insulating film 6, a low insulating material of specific inductive capacity, such as methyl siloxane, can be used.

A process for forming ball bump 3b in antifuse domain 2 of semiconductor device 1 is next explained. Here, as a result of operating test of two or more circuits on semiconductor device 1, it is supposed that, the circuit which is connected to second antifuse 3 on FIG. 1 is defective, and the circuit which is connected to the other antifuse 3 is normal. Then, a ball bump 3b is not connected to the second antifuse 3 which is connected to a defective circuit and ball bumps 3b are connected to remaining antifuses 3 which are connected to a normal circuit

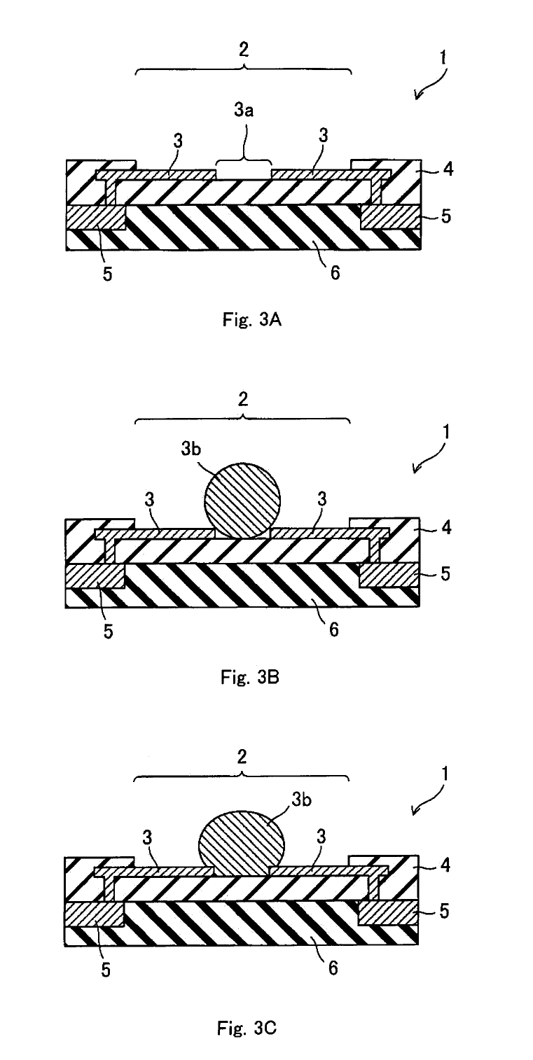

First as shown in FIG. 3A, a semiconductor device 1 in which ball bumps 3b are not formed is prepared.

Next, as shown in FIG. 3B, ball bump 3b is formed in space 3a of antifuse 3 which is connected to normal circuit in antifuse domain 2.

Next, as shown in FIG. 3C, ball bump 3b is at least partially melted by heating, and antifuse 3 is thereby electrically connected.

In addition, as alternative methods of connecting ball bump 3b and antifuse 3a method of thermo compression of ball bump 3b by a bonding head, and a method of heat-treating after forming ball bump 3b by an ink-jet method can be used.

In this embodiment although the method of connecting ball bump 3b to antifuse 3 which is connected to a normal circuit, and not connecting ball bump 3b to antifuse 3 which is connected to a defective circuit is used, ball bump 3b may be removed from antifuse 3 which is connected to a defective circuit after ball bumps 3b previously are connected to all antifuses 3. In this case, in the heat treatment process for melting ball bump 3b, for example, a ball bump 3b can be selectively removed by a solder sucker and a solder wick.

In this embodiment, since antifuses can be electrically connected by ball bumps without applying voltage, surrounding elements are not damaged by applied voltage. Therefore, it is possible to arrange an element domain near an antifuse domain, to contribute to a miniaturization of a semiconductor device.

### Second Embodiment

A difference between the first embodiment and a second embodiment is that the connection end of the antifuse is melted without using a ball bump and the antifuse is connected. This is described in the following discussion, wherein the explanation of same components in first embodiment is omitted.

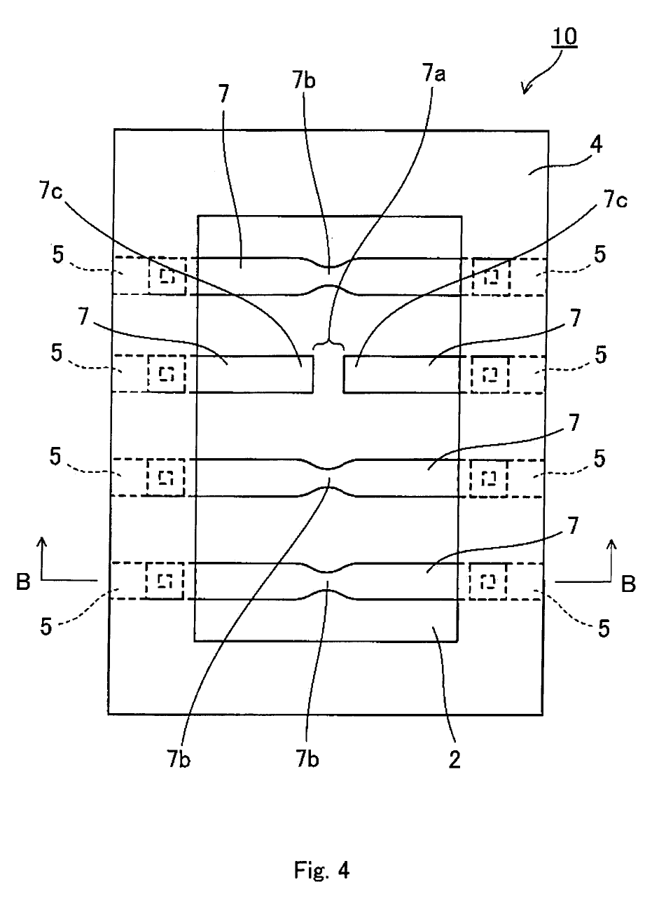

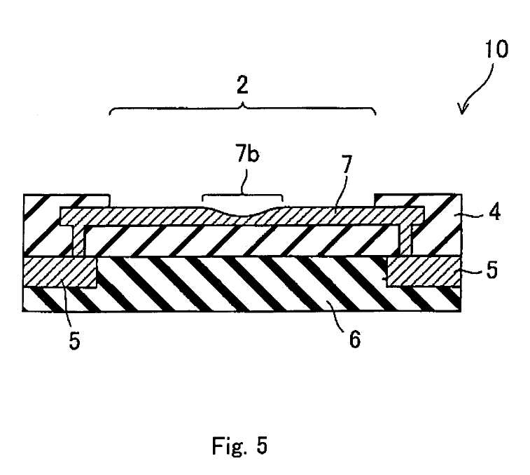

As shown in FIG. 4 and FIG. 5, semiconductor device 10 has two or more antifuses 7. Each antifuse 7 is formed in protection insulating film 4. Each antifuse 7 has an exposed surface in antifuse domain 2. Moreover, each antifuse 7 is connected to wiring 5 formed in interlayer insulating film 6, respectively.

Antifuse 7 includes of two wiring elements (wiring elements on either side in FIG. 4) electrically insulated by space 7a in antifuse domain 2. Among these, space 7a is occupied by connecting part 7b of specific antifuses 7 (1st, 3rd and 4th antifuses 7 from the top in FIG. 4), and the two wirings are connected. For example, the 1 st, 3rd and 4th antifuses 7 from the top in FIG. 4 are connected to circuits which operate normally, and the 2nd antifuse 7 is connected to a defective circuit.

Antifuse 7 is made of a conductive material such as solder, etc., by which connecting end 7c located on both sides of space 7a can be melted by irradiation of laser light. The melting point of ball bump 3b may be more than 240 degrees (° C.). Once again, the melting point must be sufficiently high to avoid melting which might otherwise occur in a subsequent heating process (for example, a heating process for activating impurity ions implanted into a transistor domain) if a melting point is too low.

Wiring 5 is made of conductive material, such as Cu.

As protection insulating film 4, insulating materials such as TEOS (Tetraethoxysilane), SiN, and polyimide or the like can be used. Especially, hygroscopic low material, such as TEOS and SiN, is desirable.

As the interlayer insulating film 6, low insulating material of specific inductive capacity, such as methyl siloxane, can be used.

Next, the process which connects antifuse 7 through connecting part 7b is explained. Here, as a result of operating test of two or more circuits on semiconductor device 10, it is supposed that, the circuit which is connected to the 2nd antifuse 7 from the top of FIG. 4 is defective, and the circuits which are connected to other antifuses 7 are normal. Then, each antifuse 7 which is connected to a normal circuit is connected via connecting part 7b, and the 2nd antifuse 7 from the top of FIG. 4 which is connected to defective circuit is not connected.

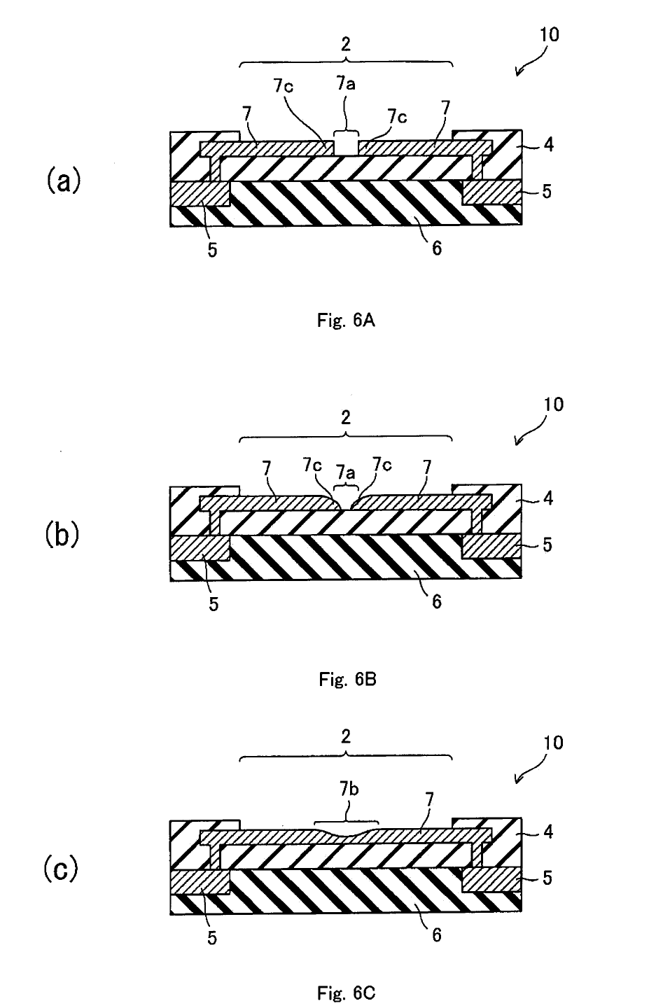

As shown in FIG. 6A, semiconductor device 10 which has antifuse 7 insulated by space 7a is prepared.

As shown in FIG. 6B, using laser etc., connecting end 7c of antifuse 7 which is connected to the normal circuit is heated locally in antifuse domain 2, and is melted.

As shown in FIG. 6C, when connecting end 7c continues to be heated, connecting end 7c begins to melt, and space 7a is occupied by connecting part 7b. Thereby, antifuse 7 is connected.

In addition, since laser light is used for heating connecting end 7c of antifuse 7, laser light does not reach to the lower layer of antifuse 7, so that there is no possibility that the lower layer of antifuse 7 may be damaged.

Moreover, either side of connecting end 7c is melted, so that space 7a may be occupied. In this case, at least melted connection end 7c may just is made of a conductive material which can be melted by irradiation of laser etc.

According to second embodiment of this invention, since the wiring which is connected to antifuse can be connected without applying voltage like the first embodiment, surrounding elements etc. are not damaged by applied voltage. Therefore, it is possible to arrange an element domain around an antifuse domain, so as to contribute to miniaturization of the semiconductor device. Moreover, the process which forms the ball bump which is connected to the antifuse can be omitted in comparison with first embodiment.

In addition, this invention is not at all limited to the details of the embodiment above described, and this invention can otherwise be practiced within the main point of this invention.

While the invention is subject to various modifications and alternative forms, specific embodiments thereof are shown by way of embodiment in the drawings and the accompanying detailed description. It should be understood that the drawings and detailed description are not intended to limit the invention to the particular embodiments which are described. This disclosure is instead intended to cover all modifications, equivalents and alternatives falling within the scope of the present invention as defined by the appended claims.

What is claimed is:

1. A semiconductor device comprising:
a semiconductor substrate;
an insulating layer formed on the semiconductor substrate;
a wiring formed in the insulating layer; and
an antifuse including first and second connecting portions coupled to the wiring and having an space between the first connecting portion and the second connecting portion, the space having a width for insulating the first connecting portion from the second connecting portion, the first connecting portion and the second connecting portion configured to be coupled by a conductive material disposed in the space.

2. The semiconductor device according to claim 1,
wherein the conductive material is bump.

3. The semiconductor device according to claim 1,
wherein the conductive material is formed by melting at least one of the first connecting portion or the second connecting portion disposed in said space.

4. The semiconductor device according to claim 1, wherein the conductive material has a melting point greater than 240 degrees (° C.).

5. A semiconductor device comprising:
a semiconductor substrate;
an insulating layer formed on the semiconductor substrate;
a wiring formed in the insulating layer,
a first antifuse including a first connecting portion and a second connecting portion coupled to the wiring, the first connecting portion and the second connecting portion coupled by a conductive material; and
a second antifuse including a third connecting portion and a fourth connecting portion coupled to the wiring, the second antifuse having a space between the third connecting portion and the fourth connecting portion, the space having a width insulating the third connecting portion from the fourth connecting portion.

6. The semiconductor device according to claim 5,
wherein the conductive material is a ball bump.

7. The semiconductor device according to claim 5, wherein the conductive material is formed by melting at least one of the first connecting portion or the second connecting portion.

8. The semiconductor device according to claim 5, wherein a melting point of the conductive material is greater than 240 degrees (° C.).

9. The semiconductor device according to claim 5, wherein
the first antifuse is coupled to a defective circuit, and
the second antifuse is coupled to a normal circuit.

10. The semiconductor device according to claim 1, wherein the antifuse is coupled to a normal circuit.

11. A method of fabricating a semiconductor device comprising:
preparing a semiconductor substrate, an insulating layer formed on the semiconductor substrate, a wiring formed in the insulating layer, and an antifuse including a first connecting portion and the second connecting portion, separated by a space, the space having a width insulating the first connecting portion from the second connecting portion; and
disposing a conductive material in the space between the first connecting portion and the second connecting portion.

12. The method according to claim 11, wherein the disposing step comprises:
disposing a ball bump in the space.

13. The method according to claim 11, wherein the disposing step comprises:
melting part of at least one of the first connecting portion or the second connecting portion.

14. The method according to claim 11, wherein a melting point of the conductive material is greater than 240 degrees (° C.).

15. The method according to claim 11, wherein the disposing step comprises:
disposing the conductive material in the space when the antifuse is coupled to a normal circuit.

16. The method according to claim 13, wherein the melting comprise heating with a laser.

17. The method according to claim 11, wherein the preparing step comprises:
preparing first and second antifuse, the first antifuse
coupled to a normal circuit, the second antifuse coupled to a defective circuit, and
wherein the disposing step comprises
disposing the conductive material in the first antifuse.

18. A semiconductor device comprising:
a semiconductor substrate;
an insulating layer formed on the semiconductor substrate;
a wiring formed in the insulating layer,
a first antifuse including first and second connecting portions coupled to the wiring by a conductive material; and
a second antifuse including third and fourth connecting portions coupled to the wiring, the second antifuse having an space between the third connecting portion and the fourth connecting portion, the space having a width insulating the third connecting portion from the fourth connecting portion,
wherein the conductive material is a ball bump,
wherein the first antifuse is coupled to a normal circuit and
wherein the second antifuse is coupled to a defective circuit.
